(19) United States
(12) Patent Application Publication
(10) Pub. No.: US 2023/0008074 A1
(43) Pub. Date: Jan. 12, 2023

(54) ETCHING APPARATUS AND METHOD OF CONTROLLING SAME

(71) Applicant: ZEUS CO., LTD., Hwaseong-si (KR)

(72) Inventors: Seung Hoon LEE, Hwaseong-si (KR); Sung Won MO, Hwaseong-si (KR); Yang Ho LEE, Osan-si (KR); Heung Soo HAN, Osan-si (KR); Jeong Hyun BAE, Hwaseong-si (KR)

(73) Assignee: ZEUS CO., LTD., Hwaseong-si (KR)

(21) Appl. No.: 17/859,612

(22) Filed: Jul. 7, 2022

(30) Foreign Application Priority Data
Jul. 8, 2021 (KR) 10-2021-0089414

(51) Int. Cl. H01L 21/67; C23C 16/44

(52) U.S. Cl. CPC H01L 21/67063; C23C 16/4412

(57) ABSTRACT

The present invention relates to an etching apparatus including an etching chamber in which a target object is etched by an etchant, an etchant supply part which collects the etchant in the etching chamber and supplies the etchant to the etching chamber using an etchant pump, a gas circulation pipe connected from a predetermined point of an upper portion of the etchant supply part to a predetermined point of an upper portion of the etching chamber and formed to circulate a gas, and an air pump formed at one side of the gas circulation pipe and configured to forcibly circulate the gas.

### CROSS-REFERENCE TO RELATED APPLICATION

This application claims priority to and the benefit of Korean Patent Application No. 10-2021-0089414, filed on Jul. 8, 2021, the disclosure of which is incorporated herein by reference in its entirety.

### BACKGROUND

### 1. Field of the Invention

The present invention relates to an etching apparatus and a method of controlling the same, and more specifically, to an etching apparatus in which an etchant is smoothly naturally drained from an etching chamber to an etchant supply part even in a pressurized state of an etching part of the etching apparatus, and a method of controlling the same.

### 2. Discussion of Related Art

Generally, semiconductor front end processes include etching processes, and the etching processes include dry etching processes and wet etching processes.

Dry etching processes are mainly performed in a vacuum state using a fluorine-based gas and an inert gas, and since apparatuses for performing the dry etching processes are expansive, there is a limit to commercial use of the dry etching processes. Accordingly, wet etching processes using phosphoric acid are more widely used than the dry etching processes.

A wet etching process is a process of selectively etching a desired target layer from a target object (substrate or the like) through a chemical reaction and is performed using an etchant mixed and composited to have a composition ratio corresponding to required characteristics or an etch rate.

Wet etching processes have advantages of more improved process compatibility than dry etching processes, the ability to process many target objects at once, and the low prices of the apparatuses.

However, when etching is performed during a wet etching process, since an etchant is partially vaporized, a temperature of a target object may be lowered due to evaporation heat, it is difficult to control a concentration of the etchant due to evaporation of the etchant, and thus there is a disadvantage that a loss occurs. Accordingly, a method of maintaining a uniform concentration of an etchant by pressurizing an etching part (for example, including an etching chamber and an etchant supply part), that is, forming the etching part as a pressurizing system pressurized at a predetermined pressure, to prevent a vaporization phenomenon of the etchant in the etching part is required.

However, when the etching part is pressurized as described above (that is, the etching part is formed as the pressurizing system), and an etchant pump is driven in a high-temperature pressurized state, a phenomenon in which a pump bellows is deformed (for example, expanded) due to a difference between pressures and temperatures of an inside and outside of the pump and comes into contact with an inner wall (for example, an inner guide) of the pump occurs, and as friction between the pump bellows and the inner wall continues, damage to a part occurs (for example, a phenomenon in which a friction portion of the bellows is worn occurs), which reduces the lifetime, degrades performance of the pump, and may ultimately cause an incident when the bellows breaks in the high-temperature pressurized state.

In addition, when the etching part is pressurized as described above, since a pressure in the etching chamber of the etching part and a pressure in the etchant supply part become the same, there is a problem that natural drainage (that is, a method of naturally draining the etchant in the etching chamber to an etchant supply part disposed under the etching chamber using gravity even without using power (for example, a pump which forcibly discharges the etchant from the etching chamber to the etchant supply part) of the etchant in the etching chamber is not easy.

When the drainage of the etchant is not smoothly performed and the etching chamber is immersed in the etchant, there are problems that a process cannot be performed using the etching chamber, the etchant permeates a part connected to the etching chamber causing corrosion or deformation, and thus the etching part is broken.

Accordingly, technology of preventing damage to a bellows in an etchant pump which transfers an etchant from an etchant supply part in an etching part to an etching chamber and smoothly naturally draining the etchant from the etching chamber to the etchant supply part even in a pressurized state of the etching part is required.

The related art of the present invention is disclosed in Korean Patent Registration No. 10-0691479 (Registered on Feb. 28, 2007, ETCHING CHAMBER FOR LARGE AREA SUBSTRATE).

### SUMMARY OF THE INVENTION

The present invention is directed to providing an etching apparatus capable of smoothly naturally draining etchant from an etching chamber to an etchant supply part even in a pressurized state of an etching part of the etching apparatus, and a method of controlling the same.

According to an aspect of the present invention, there is provided an etching apparatus including an etching chamber in which a target object is etched by an etchant, an etchant supply part which collects the etchant in the etching chamber and supplies the etchant to the etching chamber using an etchant pump, a gas circulation pipe connected from a predetermined point of an upper portion of the etchant supply part to a predetermined point of an upper portion of the etching chamber and formed to circulate a gas, and an air pump formed at one side of the gas circulation pipe and configured to forcibly circulate the gas.

A determined point at which the gas circulation pipe is formed may be a predetermined point of an upper portion which is positioned higher than a position of the etchant and at which the gas is positioned.

The etching apparatus may further include a control unit which controls the air pump, wherein, when the etching apparatus starts operation to supply the etchant to the etching chamber using the etchant pump, the control unit may operate the air pump at a predetermined speed.

When the operation of the etching apparatus stops, or operation of the etchant pump stops to stop the supply of the etchant to the etching chamber, the control unit may immediately stop the operation of the air pump.

The etchant supply part may collect the etchant in the etching chamber in a natural drainage manner through gravity.

The etching apparatus may further include a valve, wherein the valve may alternately operate to perform pumping operations of a first bellows and a second bellows symmetrically formed in the etchant pump, introduce a gas into any one of a gas chamber of the first bellows and a gas chamber of the second bellows, and discharge a gas present in the other gas chamber.

When the gas present in the gas chamber of the first bellows is introduced through the valve, the first bellows may operate to discharge the etchant to the etching part, and the gas present in the gas chamber of the second bellows may be discharged through the valve.

The etching apparatus may further include a back pressure adjusting unit connected to the etchant pump through at least one pipe, wherein the control unit may control a pressure applied to the back pressure adjusting unit to be the same as a pressure applied to the etching part to maintain an external pressure of the etchant pump to be the same as an internal pressure thereof.

According to another aspect of the present invention, there is provided a method of controlling an etching apparatus which includes an etching chamber, an etchant supply part which supplies an etchant to the etching chamber, a gas circulation pipe connected from a predetermined point of an upper portion of the etchant supply part to a predetermined point of an upper portion of the etching chamber and formed to circulate a gas, and an air pump formed at one side of the gas circulation pipe and configured to forcibly circulate the gas, the method including operating, by the control unit, the air pump at a predetermined speed when the etching apparatus starts operation to supply the etchant to the etching chamber using the etchant pump.

The method further including immediately stopping, by the control unit, the operation of the air pump when the etching apparatus stops operating, or the etchant pump stops operating to stop the supply of the etchant to the etching chamber.

The etchant supply part may collect the etchant in the etching chamber in a natural drainage manner through gravity and supply the etchant to the etching chamber using the etchant pump.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary view illustrating a schematic configuration of an etching apparatus according to a first embodiment of the present invention;

FIG. 2 is an exemplary view illustrating a schematic configuration of an etching apparatus according to a second embodiment of the present invention;

FIG. 3 is a flowchart for describing a method of controlling operations of the etching apparatus illustrated in FIG. 2;

FIG. 4 is an exemplary view for describing operations of an etchant pump in

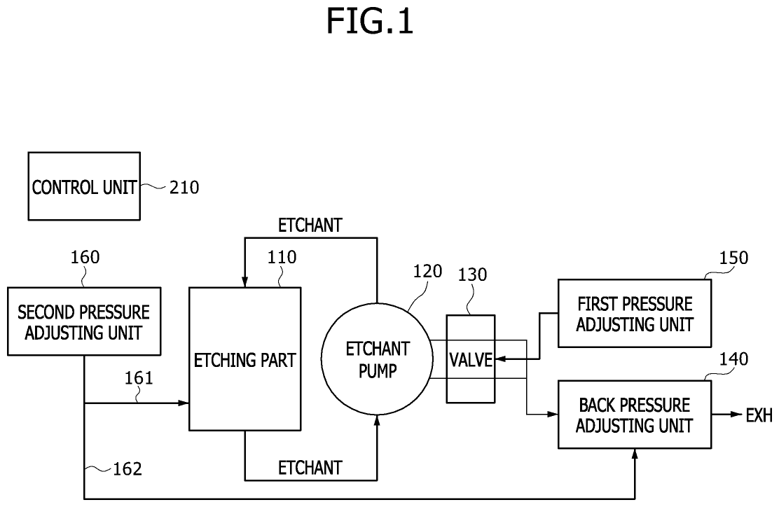

FIG. 1;

FIG. 5 is an exemplary view illustrating a detailed configuration of an etching part in FIG. 1; and

FIG. 6 is a flowchart for describing a method of controlling operations of the etching apparatus illustrated in FIG. 5.

### DETAILED DESCRIPTION OF EXEMPLARY EMBODIMENTS

Hereinafter, an etching apparatus and a method of controlling the same according to the present invention will be described with reference to the accompanying drawings.

In this description, thicknesses of lines or sizes of components in the drawings may be exaggerated for clarity and convenience of explanation. In addition, terms described below are defined in consideration of functions in the invention, and meanings of the terms may vary depending on, for example, a user or operator's intentions or customs. Therefore, the meanings of the terms should be interpreted based on content described throughout this specification.

FIG. 1 is an exemplary view illustrating a schematic configuration of an etching apparatus according to a first embodiment of the present invention

As illustrated in FIG. 1, the etching apparatus according to the first embodiment of the present invention includes an etching part 110, an etchant pump 120, a valve 130, a back pressure adjusting unit 140, a first pressure adjusting unit 150, a second pressure adjusting unit 160, and a control unit 210.

The etching part 110 includes an etching chamber 111 (see FIG. 5) and an etchant supply part 112 (see FIG. 5) and is formed as a pressurization system which pressurizes the etching chamber 111 (see FIG. 5) and the etchant supply part 112 (see FIG. 5) at the same predetermined pressure.

FIG. 5 is an exemplary view illustrating a detailed configuration of the etching part in FIG. 1 and will be specifically referenced and described when a method of solving a problem of the etching part 110 is described.

Referring to FIG. 1 again, the second pressure adjusting unit 160 forms and maintains a pressurizing atmosphere when pressurizing the etching part 110 at a predetermined pressure for etching a target object.

For example, the second pressure adjusting unit 160 applies a pressure to the etching part 110 through a pipe 161 connected to the etching part 110, and a new pipe 162 branched off from the pipe 161 is connected to the back pressure adjusting unit 140. Accordingly, the same pressure as the pressure applied to the etching part 110 is also applied to the back pressure adjusting unit 140.

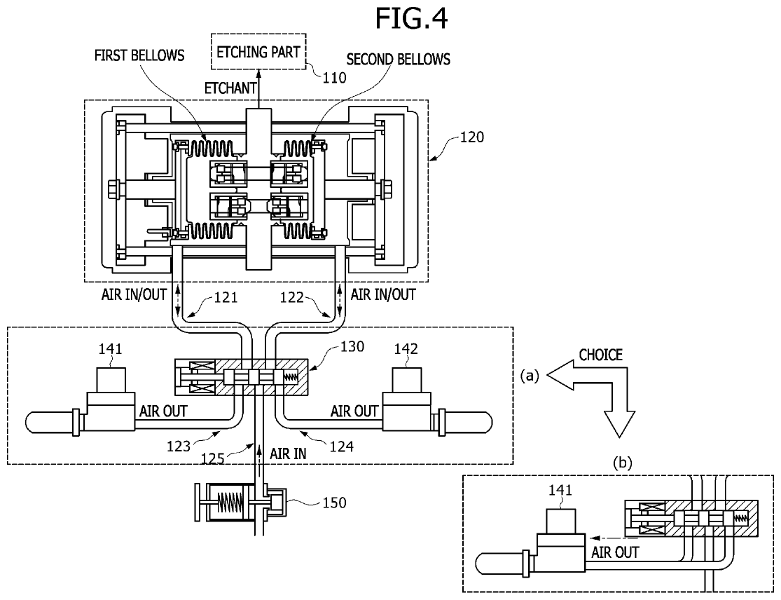

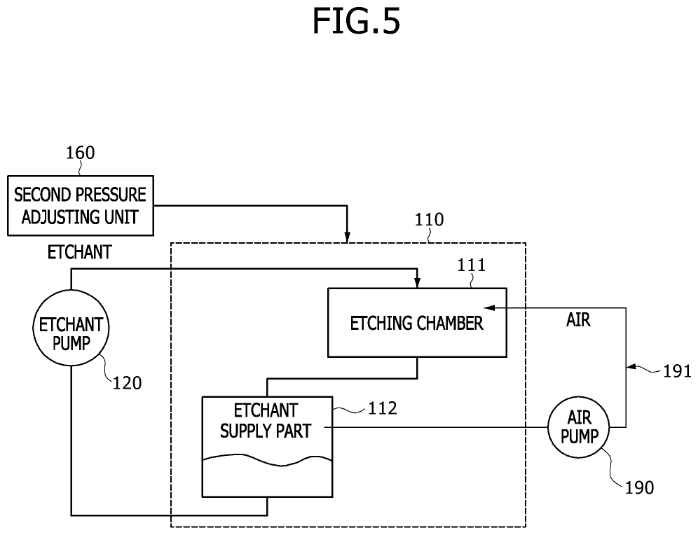

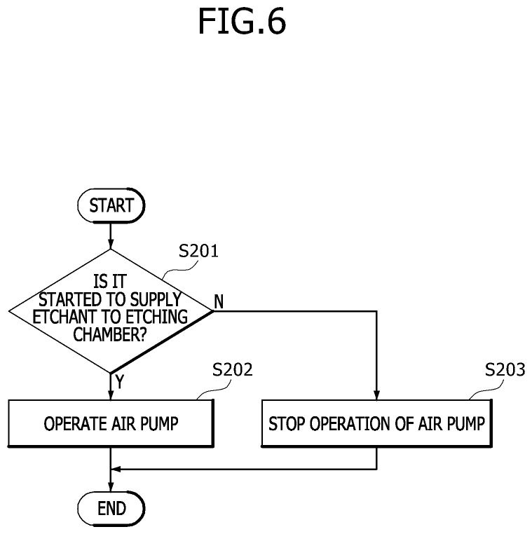

The etchant pump 120 supplies (or circulates) an etchant (or liquid chemical) to the etching part 110 in a pressurization type etching system according to the present embodiment (see FIG. 4).

FIG. 4 is an exemplary view for describing operations of the etchant pump in FIG. 1.

Referring to FIG. 4, the valve 130 (for example, a check valve) operates so that a left part and a right part alternately operate to perform pumping operations of a first bellows and a second bellows which are bilaterally symmetrically formed in the etchant pump 120 to introduce (inject) a gas (that is, a gas applied by the first pressure adjusting unit) into a gas chamber or discharge the gas introduced (injected) into the gas chamber.

In this case, the gas may include clean air, and N₂, CO₂, Ar, or the like may be used as the gas. However, the present invention is not limited thereto.

For example, when a gas is introduced into a gas chamber of the first bellows through the valve 130 (that is, when the gas is introduced into the gas chamber of the first bellows from the first pressure adjusting unit 150 through pipes 125 and 121), the first bellows operates (pumps) to discharge an etchant to the etching part 110, and in this case, a gas present in a gas chamber of the second bellows is discharged through the valve 130 (that is, the gas present in the gas chamber of the second bellows is discharged through pipes 122 and 124 and a back pressure adjusting unit 142).

Conversely, when a gas is introduced into the gas chamber of the second bellows through the valve 130 (that is, the gas is introduced into the gas chamber of the second bellows from the first pressure adjusting unit 150 through the pipes 125 and 122), the second bellows operates (pumps) to discharge an etchant, and in this case, a gas present in the gas chamber of the first bellows is discharged through the valve 130 (that is, the gas present in the gas chamber of the first bellows is discharged through the pipes 121 and 123 and a back pressure adjusting unit 141).

The back pressure adjusting units 141 and 142 are units which adjust an external pressure of the etchant pump 120, and when the gas is discharged from the etchant pump 120 and when an external pressure (for example, a pressure applied to an outer side of the bellows) is higher than a pressure applied to the back pressure adjusting units 141 and 142, the gas is discharged so as to constantly maintain an internal pressure of the etchant pump 120 (for example, a pressure by which the bellows is pushed by the pressurized etchant).

In this case, in the present embodiment, as illustrated in FIG. 4A, although the gas discharged from the etchant pump 120 through the plurality of back pressure adjusting units 141 and 142 may be discharged through different paths, as illustrated in FIG. 4B, in order to reduce a cost, the present invention may also include only one back pressure adjusting unit 141 by combining the gas discharging pipes 123 and 124 into one pipe.

As described above, when the gas discharging pipes 123 and 124 are combined into one pipe, and only one back pressure adjusting unit 141 is included in the present invention, there is an effect that a pressure adjusting unit and a pipe for applying a pressure to the back pressure adjusting unit 141 can be removed.

The first pressure adjusting unit 150 injects a gas for operating the first bellows and the second bellows of the etchant pump 120.

The gas injected through the first pressure adjusting unit 150 is injected into the gas chamber of the first bellows or the second bellows of the etchant pump 120 through the valve 130.

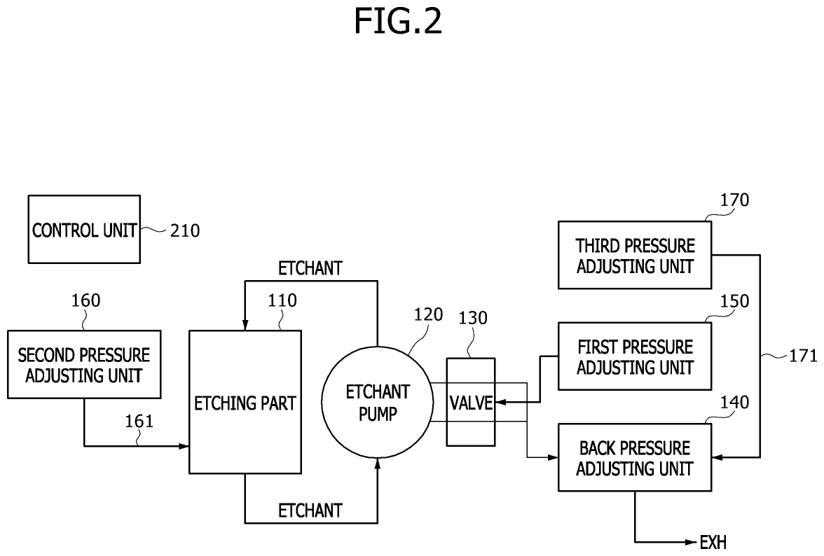

The control unit 210 controls overall operations of the etching apparatus according to the present embodiment. That is, the control unit 210 controls the first pressure adjusting unit 150, the second pressure adjusting unit 160, a third pressure adjusting unit 170 (see FIG. 2), the etching part 110, the etchant pump 120, and the valve 130.

Particularly, the control unit 210 controls the first pressure adjusting unit 150 to apply a pressure (for example, 3 bar+2 bar) which is greater than a pressure (for example, 3 bar) constantly applied to the etching part 110 and the back pressure adjusting unit 140 through the second pressure adjusting unit 160.

Accordingly, the control unit 210 controls a pressure applied to the back pressure adjusting units 140, 141, and 142 (that is, controls a pressure of the back pressure adjusting unit to be the same as a pressure applied to the etching part) to prevent damage to the bellows in the etchant pump 120. That is, there is an effect of preventing damage to the bellows by maintaining an external pressure of the etchant pump 120 (for example, a pressure applied to an outer side of the bellows) to be the same as an internal pressure (for example, a pressure by which the bellows is pushed by the pressurized etchant) to prevent deformation or friction of an inner wall of the bellows.

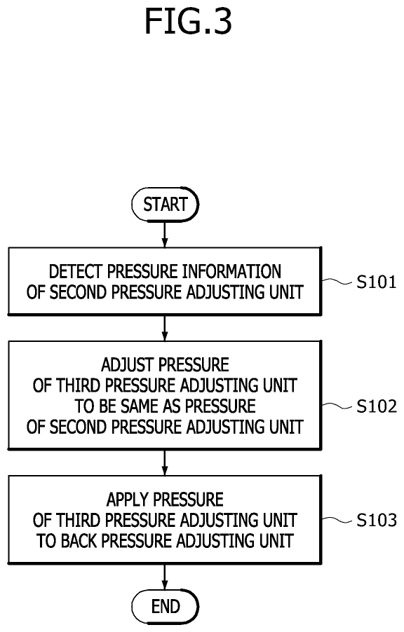

FIG. 2 is an exemplary view illustrating a schematic configuration of an etching apparatus according to a second embodiment of the present invention, and FIG. 3 is a flowchart for describing a method of controlling operations of the etching apparatus illustrated in FIG. 2.

A different point of the second embodiment illustrated in FIG. 2 from the first embodiment illustrated in FIG. 1 is that a separate third pressure adjusting unit 170 for applying a pressure to a back pressure adjusting unit 140 is added.

That is, referring to FIG. 2, a second pressure adjusting unit 160 pressurizes only an etching part 110 through a pipe 161 connected to apply a pressure to the etching part 110, a new pipe 162 is not required, the third pressure adjusting unit 170 applies a pressure to the back pressure adjusting unit 140 through a new pipe 171 connected to the back pressure adjusting unit 140, and the same pressure as a pressure applied to the etching part 110 is applied to the back pressure adjusting unit 140.

A control unit 210 controls the third pressure adjusting unit 170 to apply the same pressure as the pressure (for example, 3 bar) applied to the etching part 110 through the second pressure adjusting unit 160 to the back pressure adjusting unit 140.

In addition, the control unit 210 controls a first pressure adjusting unit 150 to apply a pressure which is greater than the pressure applied by the second pressure adjusting unit 160 or the third pressure adjusting unit 170.

Referring to FIG. 3, the control unit 210 detects pressure information of the second pressure adjusting unit 160 (S101). To this end, although not specifically illustrated in the drawings, the present invention may further include a pressure detection sensor (not shown). Alternatively, preset pressure information according to an etching process may be read from an internal memory (not shown).

In addition, the control unit 210 controls a pressure of the third pressure adjusting unit 170 to be the same as a pressure of the second pressure adjusting unit 160 (S102).

In addition, the control unit 210 applies the pressure of the third pressure adjusting unit 170 to the back pressure adjusting unit 140 (S103).

Accordingly, the control unit 210 controls the pressure applied to the back pressure adjusting unit 140 to be the same as a pressure applied to the etching part 110 to prevent damage to a bellows in an etchant pump 120. That is, there is an effect of preventing damage to the bellows by maintaining an external pressure of the etchant pump 120 (for example, a pressure applied to an outer side of the bellows) to be the same as an internal pressure (for example, a pressure by which the bellows is pushed by a pressurized etchant) to prevent deformation or friction of an inner wall of the bellows.

Meanwhile, referring to FIG. 5, the etching part 110 formed as the pressurization system is configured that the etchant supply part 112 is disposed under the etching chamber 111 so that an etchant used in an etching process in the etching chamber 111 is naturally drained to the etchant supply part 112 through an etchant drain pipe by gravity.

However, since a thickness of the etchant drain pipe is small (narrow) and a pressure of the etching chamber 111 and a pressure of the etchant supply part 112 are the same, natural drainage of the etchant is not easy.

Accordingly, in the present embodiment, a gas circulation pipe 191 connecting an upper portion of the etchant supply part 112 (for example, a predetermined point of the upper portion which is positioned higher than a position of the etchant and at which a gas is positioned) and an upper portion of the etching chamber 111 (for example, a predetermined point of the upper portion which is positioned higher than a position of the etchant and at which a gas is positioned) is formed, and an air pump 190 is formed in the middle of the gas circulation pipe 191.

The gas may include air, and thus the air pump 190 forcibly moves air, a gas, or a gas including air through the gas circulation pipe 191.

The air pump 190 forms a separate gas circulation path different from an etchant circulation path by forcibly moving a gas present in the etchant supply part 112 to the etching chamber 111 (that is, generating a pressure difference between two ends of the etchant supply part 112 and the etching chamber 111). By forcibly moving the gas using the air pump 190 as described above, the etchant and the gas of the etching chamber 111 are drained (discharged) to the etchant supply part 112 through the etchant drain pipe in order to maintain a pressure balance (that is, in order to remove a pressure difference).

FIG. 6 is a flowchart for describing a method of controlling operations of the etching apparatus illustrated in FIG. 5, and shows that when the etching apparatus starts operation to supply an etchant to the etching chamber 111 through the etchant pump 120 (Y in S201), the control unit 210 operates the air pump 190 at a predetermined speed (S202).

Accordingly, as a gas present in the etchant supply part 112 is forcibly moved to the etching chamber 111, the etchant and the gas of the etching chamber 111 are drained (discharged) to the etchant supply part 112 through the etchant drain pipe in order to maintain a pressure balance. That is, even in a pressurized state of the etching part 110, the etchant is smoothly drained from the etching chamber 111 to the etchant supply part 112.

Meanwhile, when the operation of the etching apparatus stops or the operation of the etchant pump 120 stops to stop the supply of the etchant to the etching chamber 111 (N in S201), the control unit 210 immediately stops the operation of the air pump 190 (S203).

Accordingly, since the gas present in the etchant supply part 112 does not flow to the etching chamber 111, the etchant and the gas of the etching chamber 111 are not naturally drained (discharged) to the etchant supply part 112 through the etchant drain pipe.

As described above, the present embodiment has an effect of naturally draining the etchant to the etchant supply part 112 disposed under the etching chamber 111 due to gravity even without using a drain pump (not shown) which forcibly discharges the etchant from the etching chamber 111 to the etchant supply part 112 (that is, when the drain pump is used, there may be a problem in forming an etching atmosphere because synchronization between the drain pump and the etchant pump is not easy).

According to embodiments of the present invention, an etchant can be smoothly naturally drained from an etching chamber to an etchant supply part even in a pressurized state of an etching part of an etching apparatus.

While the present invention has been described with reference to embodiments illustrated in the accompanying drawings, this is merely exemplary. It will be understood by those skilled in the art that various modifications and other equivalent example embodiments may be made from the embodiments of the present invention. Therefore, the scope of the present invention is defined by the appended claims. In addition, the present invention described in this specification can be implemented through, for example, a method, a process, an apparatus, a software program, a data stream, or a signal. Even when the present invention is described as being implemented in only a single way (for example, as a method), the described features may be implemented in another way (for example, as an apparatus or program). An apparatus may be implemented using hardware, software, firmware, or the like. A method may be implemented in an apparatus such as a processor which generally indicates a processing device such as a computer, a microprocessor, an integrated circuit, and a logic device capable of being programmed. Examples of a processor also include a communication device such as a computer, a cell phone, a portable/personal digital assistant (PDA), and another device which facilitates information communication between end-users.

What is claimed is:

1. An etching apparatus comprising:
an etching chamber in which a target object is etched by an etchant;
an etchant supply part which collects the etchant in the etching chamber and supplies the etchant to the etching chamber using an etchant pump;
a gas circulation pipe connected from a predetermined point of an upper portion of the etchant supply part to a predetermined point of an upper portion of the etching chamber and formed to circulate a gas; and
an air pump formed at one side of the gas circulation pipe and configured to forcibly circulate the gas.

2. The etching apparatus of claim 1, wherein a determined point at which the gas circulation pipe is formed is a predetermined point of an upper portion is positioned higher than a position of the etchant and at which the gas is positioned.

3. The etching apparatus of claim 1, further comprising a control unit which controls the air pump,
wherein, when the etching apparatus starts operation to supply the etchant to the etching chamber using the etchant pump, the control unit operates the air pump at a predetermined speed.

4. The etching apparatus of claim 3, wherein, when the operation of the etching apparatus stops, or operation of the etchant pump stops to stop the supply of the etchant to the etching chamber, the control unit immediately stops the operation of the air pump.

5. The etching apparatus of claim 1, wherein the etchant supply part collects the etchant in the etching chamber in a natural drainage manner through gravity.

6. The etching apparatus of claim 1, further comprising a valve, wherein the valve alternately operates to perform pumping operations of a first bellows and a second bellows symmetrically formed in the etchant pump, introduces a gas into any one of a gas chamber of the first bellows and a gas chamber of the second bellows, and discharges a gas present in the other gas chamber.

7. The etching apparatus of claim 6, wherein, when the gas present in the gas chamber of the first bellows is introduced through the valve:
the first bellows operates to discharge the etchant to the etching part; and
the gas present in the gas chamber of the second bellows is discharged through the valve.

8. The etching apparatus of claim 1, further comprising a back pressure adjusting unit connected to the etchant pump through at least one pipe,
wherein the control unit controls a pressure applied to the back pressure adjusting unit to be the same as a pressure applied to the etching part to maintain an external pressure of the etchant pump to be the same as an internal pressure thereof.

9. A method of controlling an etching apparatus which includes an etching chamber, an etchant supply part which supplies an etchant to the etching chamber, a gas circulation pipe connected from a predetermined point of an upper portion of the etchant supply part to a predetermined point of an upper portion of the etching chamber and formed to circulate a gas, and an air pump formed at one side of the gas circulation pipe and configured to forcibly circulate the gas,
the method comprising operating, by the control unit, the air pump at a predetermined speed when the etching apparatus starts operation to supply the etchant to the etching chamber using the etchant pump.

10. The method of claim 9, further comprising immediately stopping, by the control unit, the operation of the air pump when the etching apparatus stops operating, or the etchant pump stops operating to stop the supply of the etchant to the etching chamber.

11. The method of claim 9, wherein the etchant supply part collects the etchant in the etching chamber in a natural drainage manner through gravity and supplies the etchant to the etching chamber using the etchant pump.
